(19) United States
(12) Patent Application Publication
(10) Pub. No.: US 2026/0044659 A1
(43) Pub. Date: Feb. 12, 2026

(54) METHOD AND DEVICE FOR FEATURE EXTRACTION OF INTEGRATED CIRCUIT LAYOUTS, AND NON-TRANSITORY COMPUTER READABLE STORAGE MEDIUM THEREOF

(71) Applicant: United Microelectronics Corp., Hsinchu (TW)

(72) Inventors: Da-Ching LIAO, Taichung City (TW); Ya-Ching CHENG, Hsinchu City (TW); Chih-Yueh LI, Taipei City (TW); Po-Jen HSIAO, New Taipei City (TW); Chien-Nan LIN, Tainan Citiy (TW); Zih-Wun PENG, Tainan City (TW); Yu-Ying HU, Tainan City (TW)

(21) Appl. No.: 18/798,879

(22) Filed: Aug. 9, 2024

(51) Int. Cl. G06F 30/392

(52) U.S. Cl. CPC G06F 30/392

(57) ABSTRACT

The application discloses a method and device for feature extraction of integrated circuit layouts and a non-transitory computer readable storage medium thereof. A circuit pattern layout file to be implemented on a semiconductor wafer is obtained from a memory. Data preparation and preprocessing is performed on the circuit pattern layout file. A deep learning model is established and trained. Transfer learning and model fusion are performed on the deep learning model. The deep learning model is used to perform image segmentation and feature extraction on the circuit pattern layout file to extract a plurality of features. Density parameters and total perimeter parameters of the plurality of features are calculated.

### TECHNICAL FIELD

The disclosure relates to a method and device for feature extraction of integrated circuit layouts and a non-transitory computer readable storage medium thereof.

### BACKGROUND

Currently, there are various methods available to achieve “feature extraction of integrated circuit layouts.” Two such methods are described below for illustration.

The first method involves manual measurement for layout feature extraction. This method uses layout software to open a Graphical Design System (GDS) file and magnifies a specific area to directly measure different copper lines and insulation layers. A GDS file is a data conversion format for integrated circuit layouts, mainly used as input data for Electronic Design Automation (EDA) software, allowing the software to present the circuit layout of each layer of an integrated circuit design in 2D. GDS files are generated by IC design companies or outsourced compilers based on different intellectual properties (IP). Although compilers may vary due to different IPs, they must adhere to a standard output format for widespread EDA software usage, resulting in the GDS II stream format.

The problems with the first method (manual measurement for layout feature extraction) include: 1. Scale limitations, making it unsuitable for large-scale or complex layout analysis; 2. Time consumption, particularly for large or complex layouts, which takes more time; 3. Potential human errors, such as selecting the wrong measurement area or recording incorrect measurement results.

The second method uses software to calculate local matrix operations. This involves using EDA tools to calculate weighted copper line widths, densities, and perimeters within a single area, specifying a fixed area size to calculate and extract features from each region.

The problems with the second method (software calculation of local matrix operations) may include: 1. The use of EDA tools requires expensive licensing fees and has platform functionality limitations, posing challenges for future use or expansion development; 2. Fixed window layout extraction may have displacement issues leading to deviations in extracted copper line widths.

FIG. 1 shows a prior art test key. The test key is a layout with repeated features. As shown in FIG. 1, the test key features include: copper line width of 4.5 μm, copper spacing of 0.8 μm, and copper density of 0.85. Through a 10 μm*10 μm extraction window, the copper line widths, copper densities, and copper perimeters of each window are obtained as shown in FIG. 1.

The extraction window is crucial for feature accuracy. However, the current methods are prone to significant errors. Therefore, to reduce expensive licensing fees and improve the accuracy of feature extraction, the industry is striving to speed up the layout feature extraction of circuit pattern layout files, increase the flexibility of extraction windows of various sizes, and integrate features of different sizes.

### SUMMARY

According to one embodiment, a feature extraction method for an integrated circuit layout is provided. The feature extraction method includes: obtaining a circuit pattern layout file to be implemented on a semiconductor wafer from a memory; performing data preparation and preprocessing on the circuit pattern layout file; establishing and training a deep learning model; performing transfer learning and model fusion on the deep learning model; using the deep learning model to perform image segmentation and feature extraction on the circuit pattern layout file to extract a plurality of features; and calculating density parameters and total perimeter parameters of the plurality of features.

According to another embodiment, a feature extraction device for an integrated circuit layout is provided. The feature extraction device includes: a processor; and a memory coupled to the processor. The processor is configured for: obtaining a circuit pattern layout file to be implemented on a semiconductor wafer from the memory; performing data preparation and preprocessing on the circuit pattern layout file; establishing and training a deep learning model; performing transfer learning and model fusion on the deep learning model; using the deep learning model to perform image segmentation and feature extraction on the circuit pattern layout file to extract a plurality of features; and calculating density parameters and total perimeter parameters of the plurality of features.

According to an alternative embodiment, a non-transitory computer readable storage medium storing a plurality of instructions is provided. When the plurality of instructions are read by a computer, the computer performs: obtaining a circuit pattern layout file to be implemented on a semiconductor wafer from the memory; performing data preparation and preprocessing on the circuit pattern layout file; establishing and training a deep learning model; performing transfer learning and model fusion on the deep learning model; using the deep learning model to perform image segmentation and feature extraction on the circuit pattern layout file to extract a plurality of features; and calculating density parameters and total perimeter parameters of the plurality of features.

### BRIEF DESCRIPTION OF THE DRAWINGS

FIG. 1 shows a prior art test key.

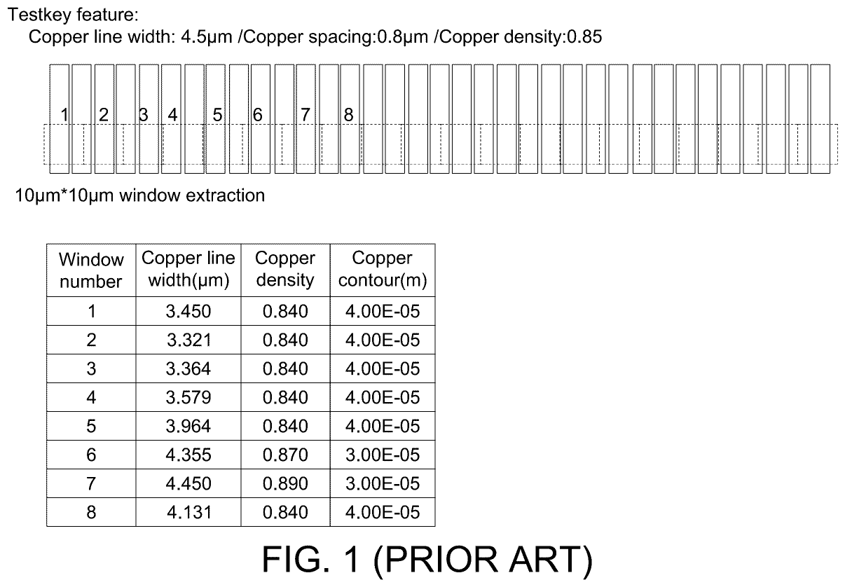

FIG. 2 illustrates a flowchart of a method for feature extraction of an integrated circuit layout according to one embodiment of the present invention.

FIG. 3 shows a circuit pattern layout file according to one embodiment of the application.

FIG. 4 shows a schematic diagram of multiple training samples cut out from the circuit pattern layout file as a training dataset according to one embodiment of the present invention.

FIG. 5 shows a multi-scale full convolution deep network architecture U-Net applicable to one embodiment of the present invention.

FIG. 6 shows a schematic diagram of training different structures of deep learning models according to one embodiment of the present invention.

FIG. 7 shows a schematic diagram of applying a random size local pattern to the trained deep learning models for segmentation, to identify the range of the copper line and the insulation layer according to one embodiment of the present invention.

FIG. 8 shows a feature extraction device for an integrated circuit layout according to one embodiment of the present invention.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

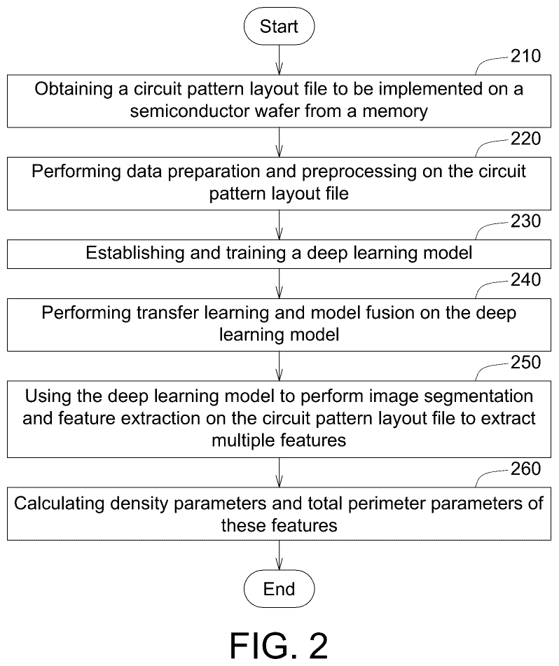

FIG. 2 illustrates a flowchart of a method for feature extraction of an integrated circuit layout according to one embodiment of the present invention. As shown in FIG. 2, the method for feature extraction of an integrated circuit layout according to one embodiment of the present invention includes: (210) obtaining a circuit pattern layout file to be implemented on a semiconductor wafer from a memory; (220) performing data preparation and preprocessing on the circuit pattern layout file; (230) establishing and training a deep learning model; (240) performing transfer learning and model fusion on the deep learning model; (250) using the deep learning model to perform image segmentation and feature extraction on the circuit pattern layout file to extract multiple features; and (260) calculating density parameters and total perimeter parameters of these features.

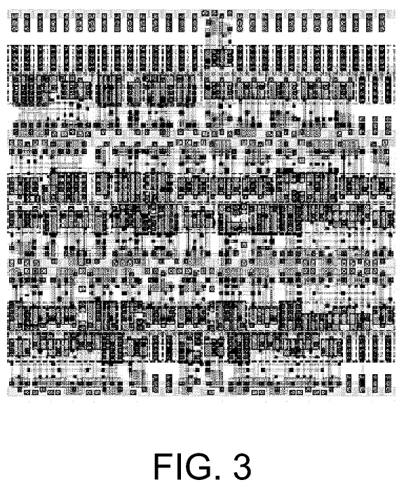

In one possible embodiment of the present invention, for example but not limited to, the circuit pattern layout file is a Graphical Design System (GDS) file, as shown in FIG. 3.

In one embodiment of the present invention, in step 220, during the data preparation and preprocessing of the circuit pattern layout file, the feature extraction method further includes: cutting out multiple patterns from the circuit pattern layout file as multiple training samples for a training dataset; and performing data augmentation (including operations such as random rotation and scaling) on these training samples to enhance feature representation at different magnifications, and performing regional annotation to indicate the position and width of a copper line and an insulation layer.

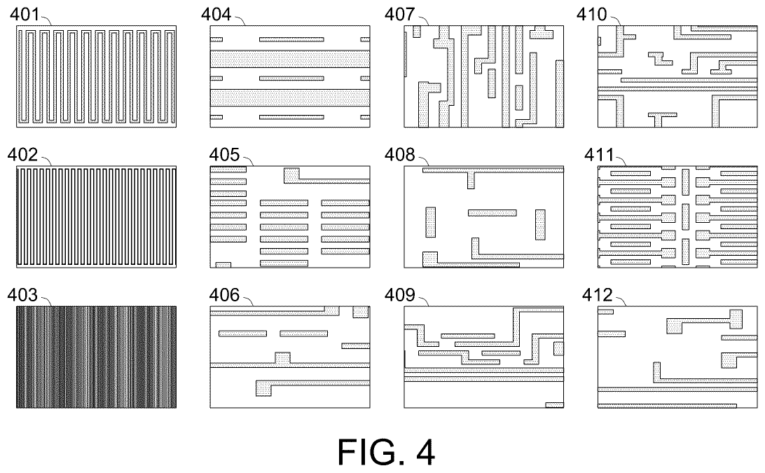

FIG. 4 shows a schematic diagram of multiple training samples cut out from the circuit pattern layout file as a training dataset according to one embodiment of the present invention. As shown in FIG. 4, the cutting size is taken as 30 μm*30 μm for illustration, but the present invention is not limited to this. In FIG. 4, twelve patterns 401-412 (each with a size of 30 μm*30 μm) are cut out from the circuit pattern layout file (such as FIG. 3). Among them, patterns 401-403 have repetitive features, while patterns 404-412 have irregular features (i.e., non-repetitive features). For example but not limited by, the patterns 401-403 are cut out from the circuit pattern layout file by picking up images of one layer of the circuit pattern layout file shown on a display screen of a computer; and the patterns 404-412 are obtained by zooming in the patterns 401-403.

In one embodiment of the present invention, in step 230, during the establishment and training of the deep learning model, the feature extraction method further includes: using a multi-scale full convolution deep network architecture as the deep learning model; training the deep learning model with multiple training samples to enable the deep learning model to identify the positions of the copper line and the insulation layer; and performing hyper-parameter tuning and network optimization, adjusting hyper-parameters such as learning rate and loss function during the training process. The multi-scale full convolution deep network architectures are specifically designed models for image segmentation (layout feature measurement) training, including but not limited to the following network models: (1) U-Net: a deep variable encoder-decoder network structure with skip connections, suitable for fine-grained image segmentation; (2) DenseNet: utilizes dense connections to improve feature transmission and reuse, reducing the number of parameters while maintaining efficiency; (3) ResNeXt: optimizes feature learning through grouped convolution, enhancing the model's generalization ability; (4) PSPNet: acquires contextual information from different regions through a pyramid pooling module, improving scene understanding and feature extraction; and (5) HRNet: maintains high-resolution channels in the model to obtain fine-grained features, suitable for precise segmentation.

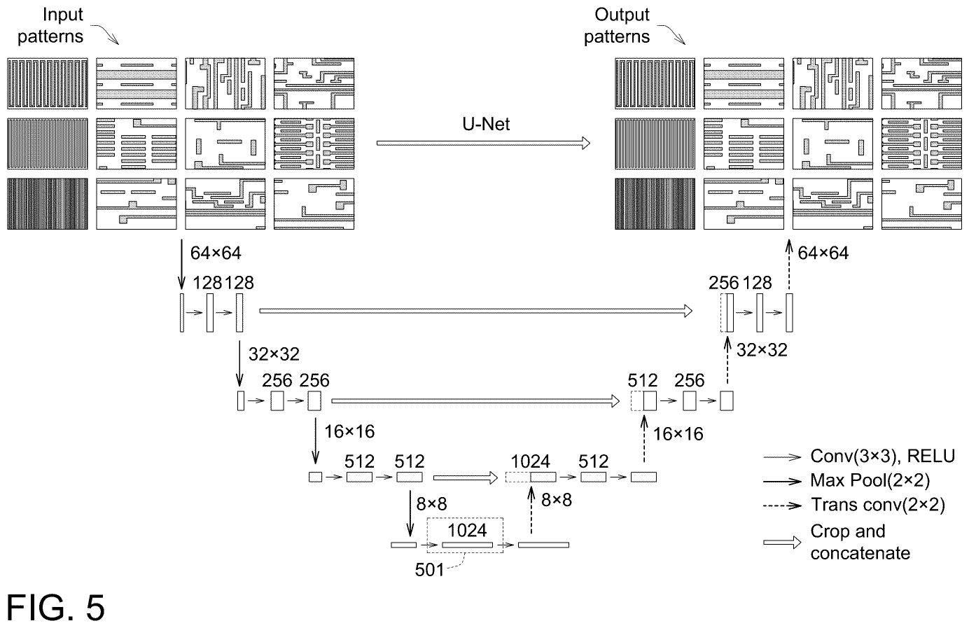

FIG. 5 shows a multi-scale full convolution deep network architecture U-Net applicable to one embodiment of the present invention. As shown in FIG. 5, the U-Net network architecture can perform filter transformation, matrix operations, etc., on the input patterns to obtain feature vectors 501. Feature vectors 501 are one of the computational units of layout features and can serve as the basis for subsequent feature measurement. Then, the U-Net network architecture can obtain output patterns based on feature vectors 501, where the higher the similarity between the output patterns and the input patterns, the better the U-Net network architecture. The operational details of the U-Net network architecture are not specifically limited herein.

In one embodiment of the present invention, in step 240, when performing transfer learning and model fusion on the deep learning model, the feature extraction method further includes: using the deep learning model for transfer learning to adapt to specific pattern segmentation tasks through fine-tuning; and training different structures of the deep learning model, then merging the multiple outputs of the different structures of the deep learning model during prediction, to optimize the stability of the prediction result through a model fusion strategy.

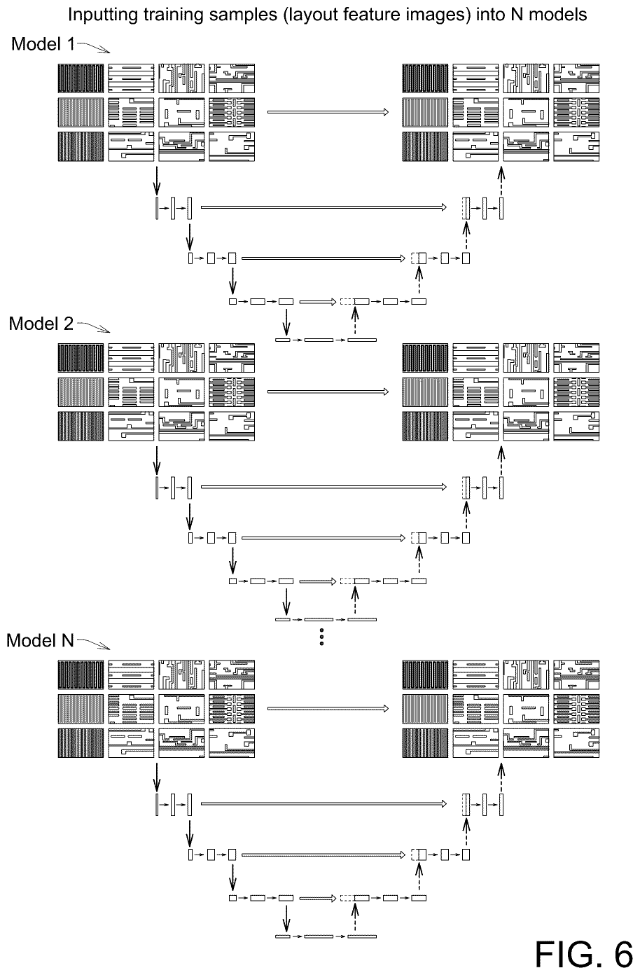

FIG. 6 shows a schematic diagram of training different structures of deep learning models (Model 1-Model N) in step 240 according to one embodiment of the present invention. The deep learning models Model 1-Model N have different structures. In FIG. 6, training samples are input into the deep learning models (Model 1-Model N) to train the deep learning models (Model 1-Model N).

In one embodiment of the present invention, in step 250, when using the deep learning model to perform image segmentation and feature extraction on the circuit pattern layout file to extract these features, the feature extraction method further includes: applying the trained deep learning model to a current local pattern of any size (the model input is not limited to the original training pattern size) for segmentation, to identify the range of the copper line and the insulation layer; extracting the width of the copper line and the width of the insulation layer from the segmented image predicted by the deep learning model; and using an image post-processing technique to optimize the segmentation results of the deep learning model, handling dummy features in layout blank spaces to avoid interference in recognition, which can improve boundary definition. In one possible embodiment of the application, the image post-processing techniques include, but are not limited to, morphology, which can perform four operations: dilation, erosion, closing, and opening.

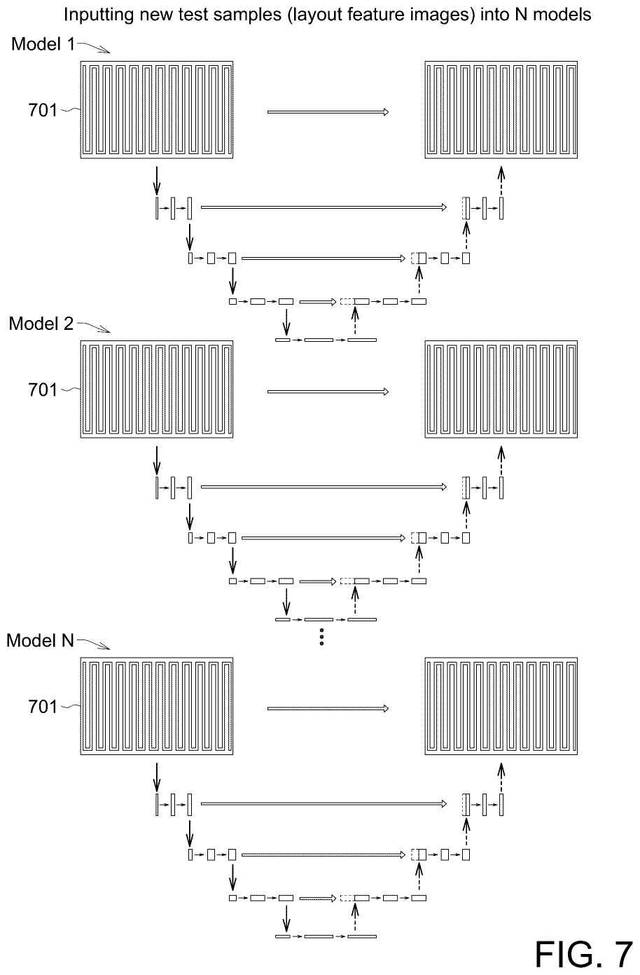

FIG. 7 shows a schematic diagram of applying a random size local pattern (the model input is not limited to the original training pattern size) to the trained deep learning models for segmentation, to identify the range of the copper line and the insulation layer, in step 250 according to one embodiment of the present invention. That is, in FIG. 7, the new test sample (layout feature image) 701 is input into the trained deep learning models Model 1-Model N, to extract the width of the copper line and the width of the insulation layer from the segmented image predicted by these deep learning models; and using an image post-processing technique to optimize the segmentation results of the deep learning model.

In one embodiment of the present invention, in step 260, when calculating the density and total perimeter of these features, the feature extraction method further includes: extracting an accurate contour of a pattern through post-processing, and using the model fusion result to calculate the density and total perimeter of a specific structure.

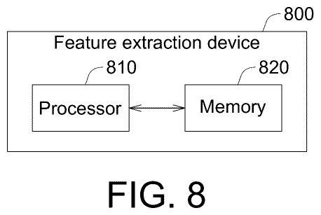

FIG. 8 shows a feature extraction device 800 for an integrated circuit layout according to one embodiment of the present invention. The feature extraction device 800 includes: a processor 810; and a memory 820 coupled to the processor 810. The processor 810 is configured for: obtaining a circuit pattern layout file implemented on a semiconductor wafer from the memory 820; performing data preparation and preprocessing on the circuit pattern layout file; establishing and training a deep learning model; performing transfer learning and model fusion on the deep learning model; using the deep learning model to perform image segmentation and feature extraction on the circuit pattern layout file to extract multiple features; and calculating density parameters and total perimeter parameters of these features. The operational details performed by the processor 810 can be referenced in the above-described method for feature extraction of an integrated circuit layout and are omitted here.

Another embodiment of the application discloses a non-transitory computer readable storage medium storing a plurality of instructions, when the plurality of instructions read by a computer, the computer performs the feature extraction method in the above embodiment of the application.

In one embodiment of the present invention, indicators for evaluating feature extraction quality include, but are not limited to, (1) Intersection over Union (IoU): calculating the overlap between the segmented area and the actual area, with higher values indicating more accurate segmentation; and/or (2) Dice Coefficient: an indicator for measuring segmentation quality based on the overlap between predicted and actual annotations.

The advantages of one embodiment of the present invention include at least: 1. Time and labor-saving: no need to spend a lot of manpower and time to measure parts of GDS files'layout; 2. Cost-saving: no need to pay for specific function licenses of EDA tools; 3. Reducing errors: avoiding the problem of displacement in fixed moving window layout extraction which leads to deviations in extracted copper line width; 4. Improving extraction window flexibility: not limited to specific size windows for extraction, and no deviation due to window displacement; 5. Enhancing feature calculation efficiency: accurately calculating copper line width, density, and perimeter through model learning of layout features, replacing manual measurement and iterative calculation by EDA tools, for layout feature extraction of different size images; 6. Optimizing layout feature accuracy: adjusting hyper-parameters in a single-size image to improve feature extraction accuracy; 7. Simulating interpretation at different magnifications similar to TEM: fine-tuning model interpretation of different size images under a pre-trained network model.

The above primarily describes the solutions provided in the embodiments of the present application from the perspective of feature extraction. It is understood that to achieve the above functions, the feature extraction device for an integrated circuit layout includes corresponding hardware structures and/or software modules that execute functions. Professionals in the technical field can easily recognize that the units and algorithm steps described in the embodiments of the present application can be implemented in hardware form or a combination of hardware and computer software. Whether the functions are performed by hardware or by hardware driven by computer software depends on the specific application and design constraints of the technical solution. Professionals in the technical field can use different methods to implement the functions described in each specific application without departing from the scope of the present application.

In one embodiment of the present application, the feature extraction device for an integrated circuit layout can be divided into functional modules based on the aforementioned method examples. For instance, each functional module can be obtained by dividing according to each corresponding function, or two or more functions can be integrated into one processing module. The integrated module can be implemented in hardware form or as a software functional module. It should be noted that in the embodiments of the present application, the division into modules is merely an example and is a logical function division. In the actual implementation process, other division methods can be used.

While many specific details have been described in this case, these should not be construed as limitations to the scope of the claimed invention, but rather as descriptions of the characteristics of specific embodiments. Certain characteristics described in the context of a single embodiment may also be implemented in combination in a single embodiment. Conversely, various characteristics described in the context of a single embodiment may be implemented individually or in any suitable sub-combination in multiple embodiments. Moreover, although the characteristics may initially be described as functioning in certain combinations, or even initially illustrated as such, in some cases one or more characteristics may be deleted from the combination, and the described combination may be directed to a sub-combination or a variation of a sub-combination. Similarly, although operations are depicted in the illustrations as occurring in a particular order, this should not be understood as requiring that such operations be performed in the specific order shown or in sequential order, or that all depicted operations must be performed to achieve the desired result.

Although the above-described embodiments disclose some examples and implementations, changes, modifications, and enhancements can be made to the described examples and implementations and other implementations based on the disclosed content.

In summary, although the present invention has been disclosed above with embodiments, it is not intended to limit the present invention. Those skilled in the art to which this invention pertains can make various changes and refinements without departing from the spirit and scope of the invention. Therefore, the scope of protection of the present invention should be defined by the appended claims.

It will be apparent to those skilled in the art that various modifications and variations can be made to the disclosed embodiments. It is intended that the specification and examples be considered as exemplars only, with a true scope of the disclosure being indicated by the following claims and their equivalents.

What is claimed is:

1. A feature extraction method for an integrated circuit layout, the feature extraction method including:
obtaining a circuit pattern layout file to be implemented on a semiconductor wafer from a memory;
performing data preparation and preprocessing on the circuit pattern layout file;
establishing and training a deep learning model;
performing transfer learning and model fusion on the deep learning model;
using the deep learning model to perform image segmentation and feature extraction on the circuit pattern layout file to extract a plurality of features; and
calculating density parameters and total perimeter parameters of the plurality of features.

2. The feature extraction method according to claim 1, wherein when performing data preparation and preprocessing of the circuit pattern layout file, the feature extraction method further including:
cutting out a plurality of patterns from the circuit pattern layout file as a plurality of training samples for a training dataset; and
performing data augmentation on the plurality of training samples, and performing regional annotation to indicate positions and widths of a copper line and an insulation layer.

3. The feature extraction method according to claim 1, wherein when performing establishment and training of the deep learning model, the feature extraction method further including:
using a multi-scale full convolution deep network architecture as the deep learning model;
training the deep learning model with a plurality of training samples to identify positions of a copper line and an insulation layer; and
performing hyper-parameter tuning and network optimization.

4. The feature extraction method according to claim 1, wherein when performing transfer learning and model fusion on the deep learning model, the feature extraction method further including:
using the deep learning model for transfer learning to adapt to pattern segmentation tasks through tuning; and
training different structures of the deep learning model, merging a plurality of outputs of the different structures of the deep learning model during prediction, to optimize stability of a prediction result through a model fusion strategy.

5. The feature extraction method according to claim 1, wherein when using the deep learning model to perform image segmentation and feature extraction on the circuit pattern layout file to extract these features, the feature extraction method further including:
applying a random size local pattern to the trained deep learning model for segmentation to identify ranges of a copper line and a insulation layer;
extracting widths of the copper line and the insulation layer from segmented images predicted by the deep learning model; and
using image post-processing technique to optimize segmentation results of the deep learning model.

6. The feature extraction method according to claim 1, wherein when calculating the density parameters and the total perimeter parameters of the plurality of features, the feature extraction method further including:
extracting a contour of a pattern through post-processing, and using the model fusion result to calculate a density parameter and a total perimeter parameter of a structure.

7. A feature extraction device for an integrated circuit layout, the feature extraction device including:
a processor; and
a memory coupled to the processor,
wherein the processor is configured for:
obtaining a circuit pattern layout file to be implemented on a semiconductor wafer from the memory;
performing data preparation and preprocessing on the circuit pattern layout file;
establishing and training a deep learning model;
performing transfer learning and model fusion on the deep learning model;
using the deep learning model to perform image segmentation and feature extraction on the circuit pattern layout file to extract a plurality of features; and
calculating density parameters and total perimeter parameters of the plurality of features.

8. The feature extraction device according to claim 7, wherein when performing data preparation and preprocessing of the circuit pattern layout file, the processor is further configured for:
cutting out a plurality of patterns from the circuit pattern layout file as a plurality of training samples for a training dataset; and
performing data augmentation on the plurality of training samples, and performing regional annotation to indicate positions and widths of a copper line and an insulation layer.

9. The feature extraction device according to claim 7, wherein when performing establishment and training of the deep learning model, the processor is further configured for:
using a multi-scale full convolution deep network architecture as the deep learning model;
training the deep learning model with a plurality of training samples to identify positions of a copper line and an insulation layer; and
performing hyper-parameter tuning and network optimization.

10. The feature extraction device according to claim 7, wherein when performing transfer learning and model fusion on the deep learning model, the processor is further configured for:
using the deep learning model for transfer learning to adapt to pattern segmentation tasks through tuning; and
training different structures of the deep learning model, merging a plurality of outputs of the different structures of the deep learning model during prediction, to optimize stability of a prediction result through a model fusion strategy.

11. The feature extraction device according to claim 7, wherein when using the deep learning model to perform image segmentation and feature extraction on the circuit pattern layout file to extract these features, the processor is further configured for:
applying a random size local pattern to the trained deep learning model for segmentation to identify ranges of a copper line and a insulation layer;
extracting widths of the copper line and the insulation layer from segmented images predicted by the deep learning model; and
using image post-processing technique to optimize segmentation results of the deep learning model.

12. The feature extraction device according to claim 7, wherein when calculating the density parameters and the total perimeter parameters of the plurality of features, the processor is further configured for:
extracting a contour of a pattern through post-processing, and using the model fusion result to calculate a density parameter and a total perimeter parameter of a structure.

13. A non-transitory computer readable storage medium storing a plurality of instructions, when the plurality of instructions read by a computer, the computer performing:
obtaining a circuit pattern layout file to be implemented on a semiconductor wafer from the memory;
performing data preparation and preprocessing on the circuit pattern layout file;
establishing and training a deep learning model;
performing transfer learning and model fusion on the deep learning model;
using the deep learning model to perform image segmentation and feature extraction on the circuit pattern layout file to extract a plurality of features; and
calculating density parameters and total perimeter parameters of the plurality of features.

14. The non-transitory computer readable storage medium according to claim 13, wherein when performing data preparation and preprocessing of the circuit pattern layout file, the computer further performing:
cutting out a plurality of patterns from the circuit pattern layout file as a plurality of training samples for a training dataset; and
performing data augmentation on the plurality of training samples, and performing regional annotation to indicate positions and widths of a copper line and an insulation layer.

15. The non-transitory computer readable storage medium according to claim 13, wherein when performing establishment and training of the deep learning model, the computer further performing:
using a multi-scale full convolution deep network architecture as the deep learning model;
training the deep learning model with a plurality of training samples to identify positions of a copper line and an insulation layer; and
performing hyper-parameter tuning and network optimization.

16. The non-transitory computer readable storage medium according to claim 13, wherein when performing transfer learning and model fusion on the deep learning model, the computer further performing:
using the deep learning model for transfer learning to adapt to pattern segmentation tasks through tuning; and
training different structures of the deep learning model, merging a plurality of outputs of the different structures of the deep learning model during prediction, to optimize stability of a prediction result through a model fusion strategy.

17. The non-transitory computer readable storage medium according to claim 13, wherein when using the deep learning model to perform image segmentation and feature extraction on the circuit pattern layout file to extract these features, the computer further performing:
applying a random size local pattern to the trained deep learning model for segmentation to identify ranges of a copper line and a insulation layer;
extracting widths of the copper line and the insulation layer from segmented images predicted by the deep learning model; and
using image post-processing technique to optimize segmentation results of the deep learning model.

18. The non-transitory computer readable storage medium according to claim 13, wherein when calculating the density parameters and the total perimeter parameters of the plurality of features, the computer further performing:
extracting a contour of a pattern through post-processing, and using the model fusion result to calculate a density parameter and a total perimeter parameter of a structure.
